(19) United States
(12) Patent Application Publication
(10) Pub. No.: US 2025/0192098 A1
(43) Pub. Date: Jun. 12, 2025

(54) SEMICONDUCTOR APPARATUS AND METHOD FOR MANUFACTURING THE SAME, AND POWER CONVERSION APPARATUS

(71) Applicant: Mitsubishi Electric Corporation, Tokyo (JP)

(72) Inventor: Yuji SATO, Chiyoda-ku, Tokyo (JP)

(73) Assignee: Mitsubishi Electric Corporation, Tokyo (JP)

(21) Appl. No.: 18/845,441

(22) PCT Filed: Mar. 23, 2022
(86) PCT No.: PCT/JP2022/013670

§ 371 Date: Sep. 10, 2024

(51) Int. Cl. H01L 23/00; H02M 7/00

(52) U.S. Cl. CPC H01L 24/85; H01L 24/45; H02M 7/003; H01L 2224/45005; H01L 2224/45013; H01L 2224/45014; H01L 2224/45124; H01L 2224/45147; H01L 2224/45541; H01L 2224/4555; H01L 2224/4556; H01L 2224/45565; H01L 2224/45624; H01L 2224/45647; H01L 2224/85205; H01L 2224/85899; H01L 2224/85986; H01L 2924/35121; H01L 2924/3701

(57) ABSTRACT

A semiconductor apparatus includes a semiconductor device, a lower wire member, and an upper wire member. The semiconductor device includes a semiconductor device body having a main surface, and a metal layer. The lower wire member includes an end surface and an end surface. In a plan view of the main surface, the end surface and the end surface are located inside a periphery of the semiconductor device. The upper wire member is stacked on the lower wire member. In the plan view of the main surface, a portion of the upper wire member is located outside the periphery of the semiconductor device. The upper wire member is joined to the metal layer with the lower wire member being interposed therebetween.

### TECHNICAL FIELD

The present disclosure relates to a semiconductor apparatus and a method for manufacturing the same, and a power conversion apparatus.

### BACKGROUND ART

Japanese National Patent Publication No. 2017-522739 (PTL 1) discloses a semiconductor apparatus including a semiconductor device, copper foil, and a copper wire, the semiconductor device including an electrode. In this semiconductor apparatus, the copper foil is disposed between the electrode of the semiconductor device and the copper wire. Specifically, the copper foil is joined to the semiconductor device via a silver-based sintering paste. The copper wire is bonded to the copper foil.

### CITATION LIST

### Patent Literature

PTL 1: Japanese National Patent Publication No. 2017-522739

### SUMMARY OF INVENTION

### Technical Problem

In order to manufacture the semiconductor apparatus in PTL 1, the step of joining the copper foil to the electrode of the semiconductor device using the silver-based sintering paste is required, which is completely different from the step of bonding the copper wire. Accordingly, the semiconductor apparatus in PTL 1 has a low productivity. The present disclosure has been made in view of the aforementioned problem, and an object of a first aspect thereof is to provide a semiconductor apparatus whose reliability and productivity can be improved, and a method for manufacturing the same. An object of a second aspect of the present disclosure is to provide a power conversion apparatus whose reliability and productivity can be improved.

### Solution to Problem

A semiconductor apparatus of the present disclosure includes a semiconductor device, a lower wire member, and an upper wire member. The semiconductor device includes a semiconductor device body having a main surface, and a metal layer provided on the main surface. The lower wire member includes a first end surface and a second end surface opposite to the first end surface. The first end surface and the second end surface are both end surfaces of the lower wire member in a longitudinal direction of the upper wire member. In a plan view of the main surface, the first end surface and the second end surface are located inside a periphery of the semiconductor device. The upper wire member is stacked on the lower wire member. In the plan view of the main surface, a portion of the upper wire member is located outside the periphery of the semiconductor device. The upper wire member is joined to the metal layer with the lower wire member being interposed therebetween.

A method for manufacturing a semiconductor apparatus of the present disclosure includes temporarily joining a lower wire member to a metal layer of a semiconductor device. The semiconductor device includes a semiconductor device body having a main surface, and the metal layer provided on the main surface. The lower wire member includes a first end surface and a second end surface opposite to the first end surface. In a plan view of the main surface, the first end surface and the second end surface are located inside a periphery of the semiconductor device. The method for manufacturing the semiconductor apparatus in the present embodiment includes stacking an upper wire member on the lower wire member. In the plan view of the main surface, a portion of the upper wire member is located outside the periphery of the semiconductor device. The first end surface and the second end surface are both end surfaces of the lower wire member in a longitudinal direction of the upper wire member. The method for manufacturing the semiconductor apparatus in the present embodiment includes permanently joining the upper wire member to the metal layer of the semiconductor device with the lower wire member being interposed therebetween.

The power conversion apparatus of the present disclosure includes a main conversion circuit and a control circuit. The main conversion circuit has the semiconductor apparatus of the present disclosure, and converts inputted power and outputs the converted inputted power. The control circuit outputs a control signal for controlling the main conversion circuit, to the main conversion circuit.

### Advantageous Effects of Invention

In the semiconductor apparatus and the method for manufacturing the same of the present disclosure, since both the upper wire member and the lower wire member are wire members, the upper wire member and the lower wire member can be joined using the same joining method. Accordingly, productivity of the semiconductor apparatus is improved. Further, since the lower wire member is disposed between the metal layer of the semiconductor device and the upper wire member, the semiconductor device is prevented from being damaged when the upper wire member is joined. Reliability of the semiconductor apparatus is improved. Furthermore, in the plan view of the main surface of the semiconductor device body, the first end surface and the second end surface of the lower wire member are located inside the periphery of the semiconductor device. Accordingly, the semiconductor device can be prevented from establishing a short circuit with a conductive member located around the semiconductor device, through the lower wire member. Reliability of the semiconductor apparatus is improved.

The power conversion apparatus of the present disclosure includes the semiconductor apparatus of the present disclosure. Accordingly, reliability and productivity of the power conversion apparatus can be improved.

### BRIEF DESCRIPTION OF DRAWINGS

FIG. 1 is a schematic plan view of a semiconductor apparatus in a first embodiment.

FIG. 2 is a schematic cross sectional view along a section line II-II shown in FIG. 1, of the semiconductor apparatus in the first embodiment.

FIG. 3 is a schematic plan view of the semiconductor apparatus in a variation of the first embodiment.

FIG. 4 is a view showing a flowchart of a method for manufacturing the semiconductor apparatus in the first embodiment.

FIG. 5 is a view showing a flowchart of the step of joining a wire member to a metal layer of a semiconductor device in the first embodiment.

FIG. 6 is a schematic cross sectional view showing one step of the method for manufacturing the semiconductor apparatus in the first embodiment.

FIG. 7 is a schematic cross sectional view showing a step subsequent to the step shown in FIG. 6, in the method for manufacturing the semiconductor apparatus in the first embodiment.

FIG. 8 is a schematic cross sectional view showing a step subsequent to the step shown in FIG. 7, in the method for manufacturing the semiconductor apparatus in the first embodiment.

FIG. 9 is a schematic cross sectional view of the semiconductor apparatus in a variation of the first embodiment.

FIG. 10 is a view showing a flowchart of a method for manufacturing the semiconductor apparatus in the variation of the first embodiment.

FIG. 11 is a schematic plan view of a semiconductor apparatus in a second embodiment.

FIG. 12 is a schematic plan view of a semiconductor apparatus in a third embodiment.

FIG. 13 is a block diagram showing a configuration of a power conversion system in a fourth embodiment.

### DESCRIPTION OF EMBODIMENTS

Hereinafter, embodiments of the present disclosure will be described. It should be noted that the same components will be designated by the same reference numerals, and the description thereof will not be repeated.

### First Embodiment

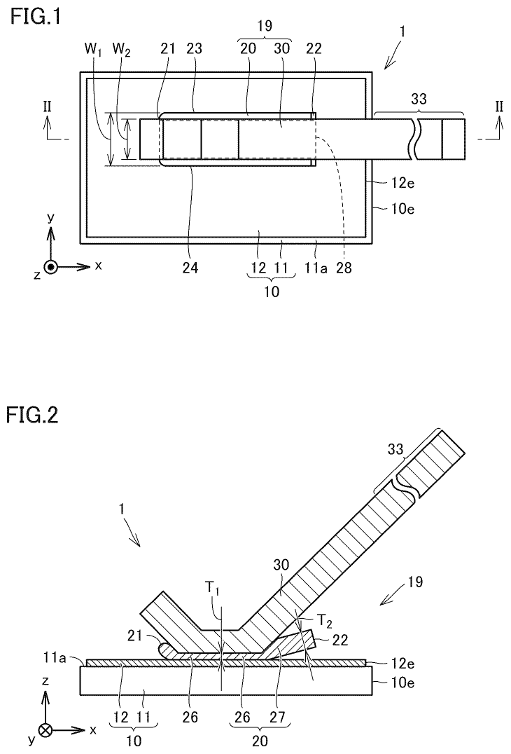

Referring to FIGS. 1 and 2, a semiconductor apparatus 1 in a first embodiment will be described. Semiconductor apparatus 1 includes a semiconductor device 10 and a wire member 19.

Semiconductor device 10 is a power semiconductor device such as an insulated gate bipolar transistor (IGBT) or a metal oxide semiconductor field effect transistor (MOSFET), for example. Semiconductor device 10 includes a semiconductor device body 11 and a metal layer 12.

Semiconductor device body 11 is mainly formed of a semiconductor material such as silicon (Si), silicon carbide (SiC), or gallium nitride (GaN). A transistor structure including a p type layer and an n type layer, for example, is incorporated into semiconductor device body 11. Semiconductor device body 11 has a main surface 11a. Main surface 11a extends in an x direction and a y direction perpendicular to the x direction, for example. A normal direction of main surface 11a is a z direction perpendicular to the x direction and the y direction. Main surface 11a of semiconductor device body 11 is formed of a semiconductor layer, an insulating layer, or a conductive layer, for example. In a plan view of main surface 11a of semiconductor device body 11, semiconductor device 10 has a periphery 10e. Periphery 10e of semiconductor device 10 is a periphery of main surface 11a, for example.

Metal layer 12 is provided on main surface 11a of semiconductor device body 11. Metal layer 12 is a conductive layer to which wire member 19 is joined, and is an electrode of semiconductor device 10, a wire layer, or a conductive pad, for example. Metal layer 12 is formed of Al, Cu, Ni, W, Co, Cr, or Ti, or an alloy of at least two metal elements among these elements, for example. Although the thickness of metal layer 12 is not particularly limited, it is more than or equal to 1 μm and less than or equal to 50 μm, for example. In the plan view of main surface 11a of semiconductor device body 11, metal layer 12 has a periphery 12e.

A diffusion barrier layer (not shown) or an adhesion layer (not shown) may be provided between semiconductor device body 11 and metal layer 12. The diffusion barrier layer prevents metal atoms forming metal layer 12 from being diffused into semiconductor device body 11. The adhesion layer improves adhesiveness between semiconductor device body 11 and metal layer 12. The diffusion barrier layer and the adhesion layer are formed of W, Co, Cr, Ti, Pd, or Pt, or an alloy of at least two metal elements among these elements, for example. An antioxidant film (not shown) may be provided on a surface of metal layer 12 exposed from semiconductor device body 11. The antioxidant film prevents metal layer 12 from being oxidized. The antioxidant film is formed of an organic material or an inorganic material, for example. The inorganic material used for the antioxidant film is a metal material such as Au, Ag, Pd, or Pt, for example.

Wire member 19 is joined to metal layer 12 of semiconductor device 10. Wire member 19 includes a lower wire member 20 and an upper wire member 30. Lower wire member 20 and upper wire member 30 are formed of a conductive material containing copper or an aluminum as a main component. Lower wire member 20 and upper wire member 30 are each a conductive wire or a conductive ribbon, for example.

As shown in FIG. 2, lower wire member 20 is disposed between metal layer 12 of semiconductor device 10 and upper wire member 30. Lower wire member 20 is joined to metal layer 12 and upper wire member 30. For example, lower wire member 20 is ultrasonically joined to metal layer 12 and upper wire member 30.

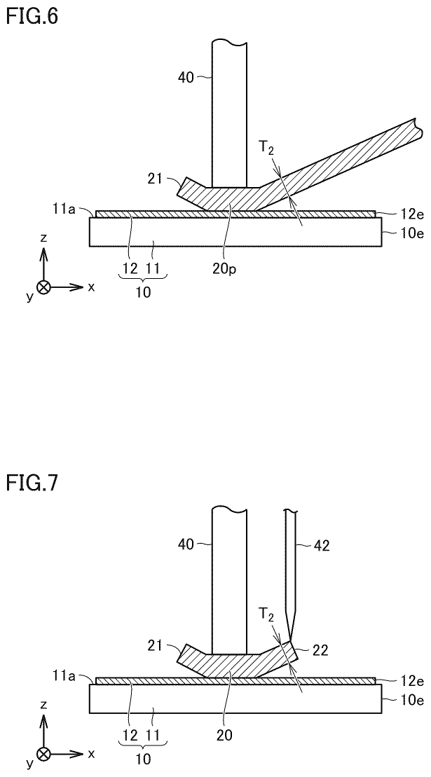

Lower wire member 20 includes a first portion 26 in contact with upper wire member 30, and a second portion 27 separated from upper wire member 30. When upper wire member 30 is joined to metal layer 12 of semiconductor device 10 with lower wire member 20 being interposed therebetween, first portion 26 of lower wire member 20 is crushed by upper wire member 30. Accordingly, a minimum thickness T₁ of first portion 26 is smaller than a maximum thickness T₂ of second portion 27. The maximum thickness of second portion 27 is the thickness of lower wire member 20 before upper wire member 30 is joined to metal layer 12 of semiconductor device 10 with lower wire member 20 being interposed therebetween (see FIG. 7), and is the thickness of a conductive wire member 20p (see FIG. 6). Maximum thickness T₂ of second portion 27 is more than or equal to 100 μm, for example.

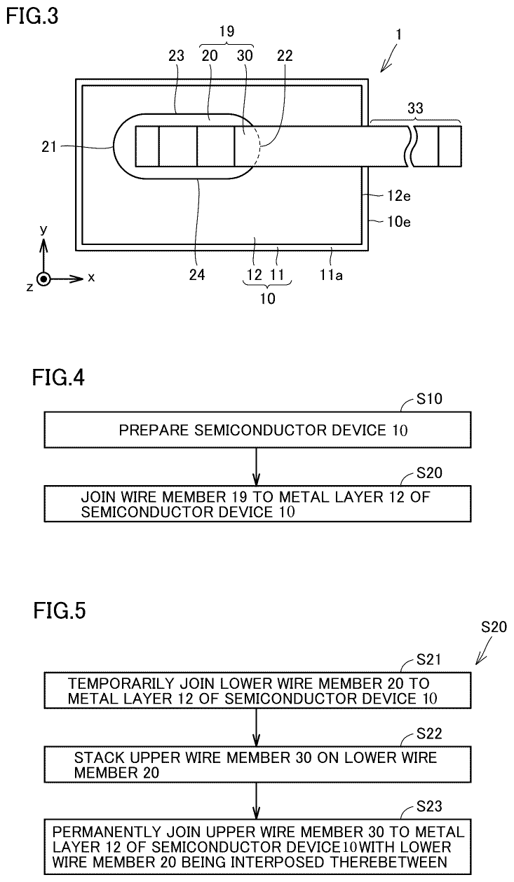

In the plan view of main surface 11a of semiconductor device body 11, lower wire member 20 may have an elongated shape in a longitudinal direction of upper wire member 30 (the x direction). The shape of lower wire member 20 may be a substantially rectangular shape (see FIG. 1), may be a shape having semicircles combined at both short sides of a rectangle (see FIG. 3), or may be an ellipse or a polygon, for example. In the plan view of main surface 11a of semiconductor device body 11, the shape of lower wire member 20 may be a square, a circle, or a regular polygon, for example.

Referring to FIGS. 1 and 2, lower wire member 20 includes an end surface 21 and an end surface 22 opposite to end surface 21. End surface 21 and end surface 22 are both end surfaces of lower wire member 20 in the longitudinal direction of upper wire member 30 (the x direction). When lower wire member 20 has an elongated shape in the longitudinal direction of upper wire member 30 in the plan view of main surface 11a of semiconductor device body 11, end surface 21 and end surface 22 are both end surfaces in a longitudinal direction of lower wire member 20. At least one of end surface 21 or end surface 22 is a cut end surface. The cut end surface is an end surface formed by cutting conductive wire member 20p (for example, a conductive wire or a conductive ribbon) with a cutter 42, as shown in FIG. 7. In the present embodiment, end surface 22 is a cut end surface. End surface 21 may also be a cut end surface. Each of end surface 21 and end surface 22 may be a flat surface, or a curved surface.

Referring to FIG. 1, in the plan view of main surface 11a of semiconductor device body 11, lower wire member 20 includes an edge 23 and an edge 24. Each of edge 23 and edge 24 is connected to end surface 21 and end surface 22. Edge 23 and edge 24 extend in the longitudinal direction of upper wire member 30 (the x direction). Edge 23 and edge 24 face each other in a transverse direction of upper wire member 30 (the y direction). In the plan view of main surface 11a of semiconductor device body 11, the transverse direction of upper wire member 30 is perpendicular to the longitudinal direction of upper wire member 30.

When lower wire member 20 has an elongated shape in the longitudinal direction of upper wire member 30 in the plan view of main surface 11a of semiconductor device body 11, each of edge 23 and edge 24 extends in the longitudinal direction of lower wire member 20. When lower wire member 20 has an elongated shape in the longitudinal direction of upper wire member 30 in the plan view of main surface 11a of semiconductor device body 11, edge 23 and edge 24 face each other in a transverse direction of lower wire member 20. In the plan view of main surface 11a of semiconductor device body 11, the transverse direction of lower wire member 20 is perpendicular to the longitudinal direction of lower wire member 20.

In the plan view of main surface 11a of semiconductor device body 11, end surface 21 and end surface 22 of lower wire member 20 are located inside periphery 10e of semiconductor device 10. In the plan view of main surface 11a of semiconductor device body 11, end surface 21 and end surface 22 of lower wire member 20 may be located inside periphery 10e of metal layer 12.

Referring to FIG. 2, upper wire member 30 is stacked on lower wire member 20. Upper wire member 30 is joined to metal layer 12 with lower wire member 20 being interposed therebetween. Metal layer 12, lower wire member 20, and upper wire member 30 are stacked in the normal direction of main surface 11a of semiconductor device body 11 (the z direction).

Referring to FIGS. 1 and 2, in the plan view of main surface 11a of semiconductor device body 11, a portion 33 of upper wire member 30 is located outside periphery 10e of semiconductor device 10. In the plan view of main surface 11a of semiconductor device body 11, portion 33 of upper wire member 30 is located outside periphery 10e of metal layer 12. Portion 33 of upper wire member 30 is joined to another semiconductor device 10 (not shown) or circuit pattern (not shown).

Referring to FIG. 1, when lower wire member 20 has an elongated shape in the longitudinal direction of upper wire member 30 in the plan view of main surface 11a of semiconductor device body 11, the longitudinal direction of upper wire member 30 extends along the longitudinal direction of lower wire member 20. The longitudinal direction of upper wire member 30 may be parallel or may not be parallel to the longitudinal direction of lower wire member 20. The angle between the longitudinal direction of upper wire member 30 and the longitudinal direction of lower wire member 20 is more than or equal to 0° and less than 45°. This angle may be less than or equal to 30°, may be less than or equal to 20, or may be less than or equal to 10°.

Referring to FIG. 1, in the plan view of main surface 11a of semiconductor device body 11, a width W₂ of upper wire member 30 in the transverse direction of upper wire member 30 is smaller than a width W₁ of lower wire member 20 in the transverse direction of upper wire member 30. In the plan view of main surface 11a of semiconductor device body 11, an entire width in the transverse direction of upper wire member 30 (for example, the y direction), of a portion 28 of upper wire member 30 located between end surface 21 and end surface 22 of lower wire member 20, overlaps lower wire member 20. That is, in the plan view of main surface 11a of semiconductor device body 11, the entire width in the transverse direction of upper wire member 30, of portion 28 of upper wire member 30 located between end surface 21 and end surface 22 of lower wire member 20, is located between edge 23 and edge 24 of lower wire member 20. In the plan view of main surface 11a of semiconductor device body 11, portion 28 of upper wire member 30 located between end surface 21 and end surface 22 of lower wire member 20 does not protrude from lower wire member 20 in the transverse direction of upper wire member 30.

Mainly referring to FIGS. 4 to 8, a method for manufacturing semiconductor apparatus 1 in the present embodiment will be described.

Referring to FIG. 4, the method for manufacturing semiconductor apparatus 1 includes preparing semiconductor device 10 (S10). As shown in FIG. 1, semiconductor device 10 includes semiconductor device body 11 and metal layer 12. Semiconductor device body 11 has main surface 11a. Metal layer 12 is provided on main surface 11a of semiconductor device 10. Metal layer 12 is formed by chemical vapor deposition (CVD), physical vapor deposition (PVD) such as sputtering, or plating, for example. Preparing semiconductor device 10 includes manufacturing semiconductor device 10 using a known manufacturing method, or purchasing semiconductor device 10, for example.

Referring to FIG. 4, the method for manufacturing semiconductor apparatus 1 includes joining wire member 19 to metal layer 12 of semiconductor device 10 (S20). Wire member 19 includes lower wire member 20 and upper wire member 30.

Referring to FIG. 5, joining wire member 19 to metal layer 12 of semiconductor device 10 (S20) includes temporarily joining lower wire member 20 to metal layer 12 of semiconductor device 10 (S21).

For example, as shown in FIG. 6, conductive wire member 20p is stacked on metal layer 12 of semiconductor device 10. Conductive wire member 20p includes end surface 21. Conductive wire member 20p is formed of the same material as that for lower wire member 20, and is longer than lower wire member 20.

Then, as shown in FIGS. 6 and 7, conductive wire member 20p is temporarily joined to metal layer 12 of semiconductor device 10, using a ultrasonic horn 40. Specifically, as shown in FIG. 6, conductive wire member 20p is ultrasonically joined to metal layer 12 of semiconductor device 10, while applying a first load and first ultrasonic vibration energy to conductive wire member 20p, using ultrasonic horn 40. Then, as shown in FIG. 7, conductive wire member 20p is cut, using a cutter 42. Thus, lower wire member 20 temporarily joined to metal layer 12 of semiconductor device 10 is obtained.

Lower wire member 20 includes end surface 21 and end surface 22 opposite to end surface 21. End surface 22 of lower wire member 20 is a cut end surface. When lower wire member 20 has an elongated shape in the plan view of main surface 11a of semiconductor device body 11, end surface 21 and end surface 22 are both end surfaces of lower wire member 20 in the longitudinal direction of lower wire member 20. In the plan view of main surface 11a of semiconductor device body 11, end surface 21 and end surface 22 are located inside periphery 10e of semiconductor device 10. Then, ultrasonic horn 40 and cutter 42 are moved away from lower wire member 20.

Referring to FIG. 5, joining wire member 19 to metal layer 12 of semiconductor device 10 (S20) includes stacking upper wire member 30 on lower wire member 20 (S22). In the plan view of main surface 11a of semiconductor device body 11, portion 33 of upper wire member 30 is located outside periphery 10e of semiconductor device 10. End surface 21 and end surface 22 are both end surfaces of lower wire member 20 in the longitudinal direction of upper wire member 30 (the x direction).

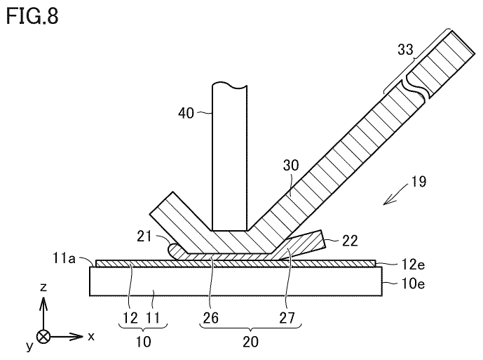

Referring to FIGS. 5 and 8, joining wire member 19 to metal layer 12 of semiconductor device 10 (S20) includes permanently joining upper wire member 30 to metal layer 12 of semiconductor device 10 with lower wire member 20 being interposed therebetween (S23). For example, as shown in FIG. 8, upper wire member 30 is ultrasonically joined to metal layer 12 of semiconductor device 10 with lower wire member 20 being interposed therebetween, while applying a second load and second ultrasonic vibration energy to upper wire member 30, using ultrasonic horn 40. The second load in the permanent joining step (S23) is larger than the first load in the temporary joining step (S21), or the second ultrasonic vibration energy in the permanent joining step (S23) is smaller than the first ultrasonic vibration energy in the temporary joining step (S21). Thus, upper wire member 30 is permanently joined to metal layer 12 of semiconductor device 10 with lower wire member 20 being interposed therebetween.

The function of the present embodiment will be described.

In the present embodiment, both upper wire member 30 and lower wire member 20 are wire members. Accordingly, the same joining method such as ultrasonic joining can be adopted in the temporary joining step (S21) and the permanent joining step (S23). Productivity of semiconductor apparatus 1 is improved.

Further, in the present embodiment, the first load in the temporary joining step (S21) is smaller than the second load in the permanent joining step (S23), or the first ultrasonic vibration energy in the temporary joining step (S21) is smaller than the second ultrasonic vibration energy in the permanent joining step (S23). Accordingly, semiconductor device 10 is prevented from being damaged in the temporary joining step (S21). Further, in the permanent joining step (S23), lower wire member 20 is disposed between metal layer 12 of semiconductor device 10 and upper wire member 30. Accordingly, semiconductor device 10 is prevented from being damaged in the permanent joining step (S23), even though the second load is larger than the first load, or the second ultrasonic vibration energy is larger than the first ultrasonic vibration energy. Even when a Cu wire, which requires a load or ultrasonic vibration energy larger than that of an Al wire, is joined to metal layer 12, semiconductor device 10 is prevented from being damaged.

Referring to FIG. 9, semiconductor apparatus 1 in a variation of the present embodiment further includes an insulating sealing member 50. Insulating sealing member 50 seals semiconductor device 10, lower wire member 20, and upper wire member 30. Insulating sealing member 50 is formed of an insulating resin material such as epoxy resin, polyimide resin, polyamide resin, polyamide-imide resin, fluorine-based resin, isocyanate-based resin, or silicone resin, for example.

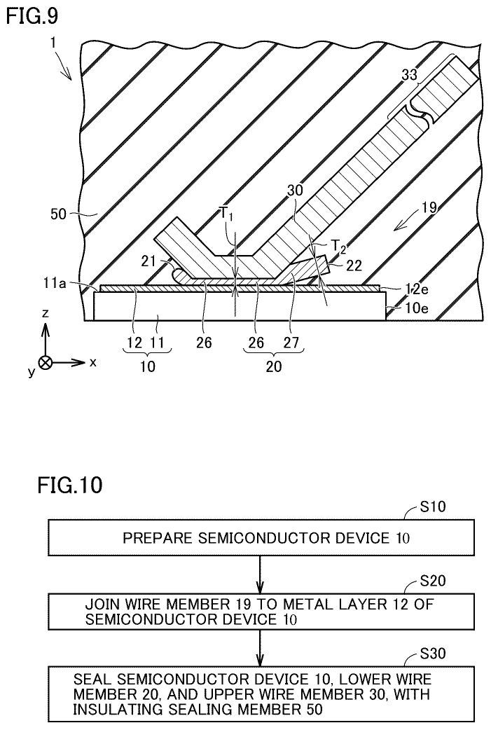

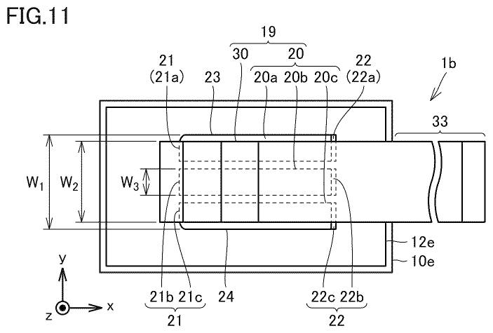

Referring to FIG. 10, a method for manufacturing semiconductor apparatus 1 in the variation of the present embodiment will be described. The method for manufacturing semiconductor apparatus 1 in the variation of the present embodiment includes steps similar to those of the method for manufacturing semiconductor apparatus 1 in the present embodiment shown in FIGS. 4 and 5, and is different from the method for manufacturing semiconductor apparatus 1 in the present embodiment mainly in the following respect. The method for manufacturing semiconductor apparatus 1 in the variation of the present embodiment further includes sealing semiconductor device 10, lower wire member 20, and upper wire member 30, with insulating sealing member 50 (S30). Step S30 is performed after step S20. Specifically, semiconductor device 10 having upper wire member 30 joined thereto with lower wire member 20 being interposed therebetween is disposed within a cavity of a frame (not shown). A sealing resin is injected into the cavity of the frame. This frame corresponds to a mold when it is a mold-type frame, and corresponds to a case when it is a case-type frame. The sealing resin is cured to form insulating scaling member 50. Thus, semiconductor device 10, lower wire member 20, and upper wire member 30 are sealed with insulating sealing member 50.

The effect of semiconductor apparatus 1 and the method for manufacturing the same in the present embodiment will be described.

Semiconductor apparatus 1 in the present embodiment includes semiconductor device 10, lower wire member 20, and upper wire member 30. Semiconductor device 10 includes semiconductor device body 11 having main surface 11a, and metal layer 12 provided on main surface 11a. Lower wire member 20 includes a first end surface (end surface 21), and a second end surface (end surface 22) opposite to the first end surface. The first end surface and the second end surface are both end surfaces of lower wire member 20 in the longitudinal direction of upper wire member 30. In the plan view of main surface 11a of semiconductor device body 11, the first end surface and the second end surface are located inside periphery 10e of semiconductor device 10. Upper wire member 30 is stacked on lower wire member 20. In the plan view of main surface 11a of semiconductor device body 11, portion 33 of upper wire member 30 is located outside periphery 10e of semiconductor device 10. Upper wire member 30 is joined to metal layer 12 with lower wire member 20 being interposed therebetween.

Since both upper wire member 30 and lower wire member 20 are wire members, upper wire member 30 and lower wire member 20 can be joined using the same joining method. Accordingly, productivity of semiconductor apparatus 1 is improved. Further, since lower wire member 20 is disposed between metal layer 12 of semiconductor device 10 and upper wire member 30, semiconductor device 10 is prevented from being damaged when upper wire member 30 is joined. Reliability of semiconductor apparatus 1 is improved. Furthermore, in the plan view of main surface 11a of semiconductor device body 11, the first end surface (end surface 21) and the second end surface (end surface 22) of lower wire member 20 are located inside periphery 10e of semiconductor device 10. Accordingly, semiconductor device 10 can be prevented from establishing a short circuit with a conductive member located around semiconductor device 10 (for example, an electrode or a conductive pad of another semiconductor device, or another wire member, or the like), through lower wire member 20. Reliability of semiconductor apparatus 1 is improved.

In semiconductor apparatus 1 in the present embodiment, at least one of the first end surface (end surface 21) or the second end surface (end surface 22) is a cut end surface. Accordingly, reliability and productivity of semiconductor apparatus 1 are improved.

In semiconductor apparatus 1 in the present embodiment, metal layer 12 and lower wire member 20 are ultrasonically joined to each other. Lower wire member 20 and upper wire member 30 are ultrasonically joined to each other. Accordingly, reliability and productivity of semiconductor apparatus 1 are improved.

In semiconductor apparatus 1 in the present embodiment, lower wire member 20 includes first portion 26 in contact with upper wire member 30, and second portion 27 separated from upper wire member 30. Minimum thickness T₁ of first portion 26 is smaller than maximum thickness T₂ of second portion 27. Accordingly, heat generated in upper wire member 30 can be dissipated efficiently.

In semiconductor apparatus 1 in the present embodiment, maximum thickness T₂ of second portion 27 is more than or equal to 100 μm. Accordingly, reliability and productivity of semiconductor apparatus 1 are improved.

In semiconductor apparatus 1 in the present embodiment, in the plan view of main surface 11a, lower wire member 20 has an elongated shape, and the longitudinal direction of upper wire member 30 extends along the longitudinal direction of lower wire member 20.

Accordingly, the contact area between upper wire member 30 and lower wire member 20 increases. Semiconductor device 10 is further prevented from being damaged when upper wire member 30 is joined. Reliability of semiconductor apparatus 1 is improved.

In semiconductor apparatus 1 in the present embodiment, in the plan view of main surface 11a of semiconductor device body 11, the entire width in the transverse direction of upper wire member 30, of portion 28 of upper wire member 30 located between the first end surface (end surface 21) and the second end surface (end surface 22) of lower wire member 20, overlaps lower wire member 20. The transverse direction of upper wire member 30 is perpendicular to the longitudinal direction of upper wire member 30, in the plan view of main surface 11a of semiconductor device body 11.

Accordingly, the contact area between upper wire member 30 and lower wire member 20 increases. Semiconductor device 10 is further prevented from being damaged when upper wire member 30 is joined. Reliability of semiconductor apparatus 1 is improved.

In semiconductor apparatus 1 in the present embodiment, lower wire member 20 and upper wire member 30 are formed of a conductive material containing copper or aluminum as a main component. Accordingly, reliability and productivity of semiconductor apparatus 1 are improved.

In semiconductor apparatus 1 in the present embodiment, lower wire member 20 and upper wire member 30 are each a conductive wire or a conductive ribbon. Accordingly, reliability and productivity of semiconductor apparatus 1 are improved.

Semiconductor apparatus 1 in the present embodiment further includes insulating sealing member 50 to seal semiconductor device 10, lower wire member 20, and upper wire member 30.

Semiconductor device 10, lower wire member 20, and upper wire member 30 are protected by insulating sealing member 50. Further, since the first end surface (end surface 21) and the second end surface (end surface 22) of lower wire member 20 are located inside periphery 10e of semiconductor device 10, lower wire member 20 is short. Accordingly, the contact area between lower wire member 20 and insulating sealing member 50 decreases. A stress applied to lower wire member 20 due to a difference between the thermal expansion coefficient of lower wire member 20 and the thermal expansion coefficient of insulating sealing member 50 decreases. Lower wire member 20 is less likely to be peeled off from metal layer 12 while semiconductor apparatus 1 is used. Furthermore, since lower wire member 20 is short, a force that lower wire member 20 receives from the flowing sealing resin when the sealing resin is injected decreases. Reduction of the joining strength between lower wire member 20 and metal layer 12 when insulating sealing member 50 is formed can be prevented. Thus, reliability of semiconductor apparatus 1 is improved.

The method for manufacturing semiconductor apparatus 1 in the present embodiment includes temporarily joining lower wire member 20 to metal layer 12 of semiconductor device 10 (S21). Semiconductor device 10 includes semiconductor device body 11 having main surface 11a, and metal layer 12 provided on main surface 11a. Lower wire member 20 includes the first end surface (end surface 21), and the second end surface (end surface 22) opposite to the first end surface. In the plan view of main surface 11a of semiconductor device body 11, the first end surface and the second end surface are located inside periphery 10e of semiconductor device 10. The method for manufacturing semiconductor apparatus 1 in the present embodiment includes stacking upper wire member 30 on lower wire member 20 (S22). In the plan view of main surface 11a of semiconductor device body 11, portion 33 of upper wire member 30 is located outside periphery 10e of semiconductor device 10. The first end surface and the second end surface are both end surfaces of lower wire member 20 in the longitudinal direction of upper wire member 30. The method for manufacturing semiconductor apparatus 1 in the present embodiment includes permanently joining upper wire member 30 to metal layer 12 of semiconductor device 10 with lower wire member 20 being interposed therebetween (S23).

Since both upper wire member 30 and lower wire member 20 are wire members, upper wire member 30 and lower wire member 20 can be joined using the same joining method. Accordingly, productivity of semiconductor apparatus 1 is improved. Further, since lower wire member 20 is disposed between metal layer 12 of semiconductor device 10 and upper wire member 30, semiconductor device 10 is prevented from being damaged when upper wire member 30 is joined. Reliability of semiconductor apparatus 1 is improved. Furthermore, in the plan view of main surface 11a of semiconductor device body 11, the first end surface (end surface 21) and the second end surface (end surface 22) of lower wire member 20 are located inside periphery 10e of semiconductor device 10. Accordingly, semiconductor device 10 can be prevented from establishing a short circuit with a conductive member located around semiconductor device 10 (for example, an electrode of another semiconductor device, or another wire member, or the like), through lower wire member 20. Reliability of semiconductor apparatus 1 is improved.

In the method for manufacturing semiconductor apparatus 1 in the present embodiment, temporarily joining lower wire member 20 to metal layer 12 of semiconductor device 10 (S21) is ultrasonically joining lower wire member 20 to metal layer 12 of semiconductor device 10 while applying the first load and the first ultrasonic vibration energy to lower wire member 20. Permanently joining upper wire member 30 to metal layer 12 of semiconductor device 10 with lower wire member 20 being interposed therebetween (S23) is ultrasonically joining upper wire member 30 to metal layer 12 of semiconductor device 10 with lower wire member 20 being interposed therebetween while applying the second load and the second ultrasonic vibration energy to upper wire member 30. The first load is smaller than the second load, or the first ultrasonic vibration energy is smaller than the second ultrasonic vibration energy.

Accordingly, semiconductor device 10 is prevented from being damaged in the temporary joining step (S21). Further, in the permanent joining step (S23), since lower wire member 20 is disposed between metal layer 12 of semiconductor device 10 and upper wire member 30, semiconductor device 10 is prevented from being damaged in the permanent joining step (S23). Reliability of semiconductor apparatus 1 is improved.

The method for manufacturing semiconductor apparatus 1 in the present embodiment further includes sealing semiconductor device 10, lower wire member 20, and upper wire member 30, with insulating sealing member 50 (S30).

Semiconductor device 10, lower wire member 20, and upper wire member 30 are protected by insulating sealing member 50. Further, since the first end surface (end surface 21) and the second end surface (end surface 22) of lower wire member 20 are located inside periphery 10e of semiconductor device 10, lower wire member 20 is short. Accordingly, the contact area between lower wire member 20 and insulating sealing member 50 decreases. The stress applied to lower wire member 20 due to the difference between the thermal expansion coefficient of lower wire member 20 and the thermal expansion coefficient of insulating sealing member 50 decreases. Lower wire member 20 is less likely to be peeled off from metal layer 12 while semiconductor apparatus 1 is used. Furthermore, since lower wire member 20 is short, the force that lower wire member 20 receives from the flowing sealing resin when the sealing resin is injected decreases. Reduction of the joining strength between lower wire member 20 and metal layer 12 when insulating sealing member 50 is formed can be prevented. Thus, reliability of semiconductor apparatus 1 is improved.

### Second Embodiment

Referring to FIG. 11, a semiconductor apparatus 1b in a second embodiment will be described. Semiconductor apparatus 1b in the present embodiment has a configuration similar to that of semiconductor apparatus 1 in the first embodiment, and is different therefrom mainly in the following respect.

Width W₂ of upper wire member 30 in the present embodiment is larger than width W₂ of upper wire member 30 in the first embodiment. Accordingly, in semiconductor apparatus 1b in the present embodiment, a current larger than that in semiconductor apparatus 1 in the first embodiment can be passed through semiconductor device 10.

Lower wire member 20 includes a plurality of lower wires 20a, 20b, and 20c arranged in the transverse direction of upper wire member 30 (the y direction). Each of the plurality of lower wires 20a, 20b, and 20c is formed of a conductive material containing copper or aluminum as a main component, as with lower wire member 20 in the first embodiment. Each of the plurality of lower wires 20a, 20b, and 20c is a conductive wire or a conductive ribbon, for example. In the plan view of main surface 11a of semiconductor device body 11, each of the plurality of lower wires 20a, 20b, and 20c may have an elongated shape in the longitudinal direction of upper wire member 30.

Each of the plurality of lower wires 20a, 20b, and 20c includes both end surfaces, as with lower wire member 20 in the first embodiment, and at least one of the both end surfaces of each of the plurality of lower wires 20a, 20b, and 20c is a cut end surface. Specifically, lower wire 20a includes an end surface 21a, and an end surface 22a opposite to end surface 21a. At least one of end surface 21a or end surface 22a is a cut end surface. Lower wire 20b includes an end surface 21b, and an end surface 22b opposite to end surface 21b. At least one of end surface 21b or end surface 22b is a cut end surface. Lower wire 20c includes an end surface 21c, and an end surface 22c opposite to end surface 21c. At least one of end surface 21c or end surface 22c is a cut end surface. In the present embodiment, end surfaces 22a, 22b, and 22c are cut end surfaces. End surfaces 21a, 21b, and 21c may also be cut end surfaces. End surface 21 of lower wire member 20 includes end surface 21a of lower wire 20a, end surface 21b of lower wire 20b, and end surface 21c of lower wire 20c. End surface 22 of lower wire member 20 includes end surface 22a of lower wire 20a, end surface 22b of lower wire 20b, and end surface 22c of lower wire 20c.

Each of the plurality of lower wires 20a, 20b, and 20c has a width W₃ smaller than width W₂ of upper wire member 30. In the plan view of main surface 11a of semiconductor device body 11, upper wire member 30 is disposed across the plurality of lower wires 20a, 20b, and 20c. Accordingly, even when width W₁ of upper wire member 30 increases, in the plan view of main surface 11a of semiconductor device body 11, portion 28 of upper wire member 30 located between end surface 21 and end surface 22 of lower wire member 20 does not protrude from lower wire member 20 in the transverse direction of upper wire member 30.

A method for manufacturing semiconductor apparatus 1b in the present embodiment will be described. The method for manufacturing semiconductor apparatus 1b in the present embodiment includes steps similar to those of the method for manufacturing semiconductor apparatus 1 in the first embodiment, and is different therefrom mainly in the following respect. In the method for manufacturing semiconductor apparatus 1b in the present embodiment, the plurality of lower wires 20a, 20b, and 20c are temporarily joined to metal layer 12 of semiconductor device 10 in the temporary joining step (S21) shown in FIG. 5, upper wire member 30 is stacked on the plurality of lower wires 20a, 20b, and 20c in the stacking step (S22) shown in FIG. 5, and upper wire member 30 is permanently joined to metal layer 12 of semiconductor device 10 with the plurality of lower wires 20a, 20b, and 20c being interposed therebetween in the permanent joining step (S23) shown in FIG. 5.

Semiconductor apparatus 1b and the method for manufacturing for the same in the present embodiment exhibit the following effect, in addition to the effect of semiconductor apparatus 1 and the method for manufacturing the same in the first embodiment.

In semiconductor apparatus 1b in the present embodiment, lower wire member 20 includes the plurality of lower wires 20a, 20b, and 20c arranged in the transverse direction of upper wire member 30. The transverse direction of upper wire member 30 (the y direction) is perpendicular to the longitudinal direction of upper wire member 30 (the x direction), in the plan view of main surface 11a of semiconductor device body 11. In the plan view of main surface 11a of semiconductor device body 11, upper wire member 30 is disposed across the plurality of lower wires 20a, 20b, and 20c.

Accordingly, even when width W₁ of upper wire member 30 is increased in order to pass a larger current through semiconductor device 10, the plurality of lower wires 20a, 20b, and 20c can be reliably interposed between upper wire member 30 and metal layer 12. Semiconductor device 10 is prevented from being damaged when upper wire member 30 is joined. Reliability of semiconductor apparatus 1b is improved.

### Third Embodiment

Referring to FIG. 12, a semiconductor apparatus 1c in a third embodiment will be described. Semiconductor apparatus 1c in the present embodiment has a configuration similar to that of semiconductor apparatus 1 in the first embodiment, and is different therefrom mainly in the following respect.

In semiconductor apparatus 1c in the present embodiment, upper wire member 30 includes a plurality of upper wires 30a and 30b arranged in the transverse direction of upper wire member 30 (the y direction). Each of the plurality of upper wires 30a and 30b is formed of a conductive material containing copper or aluminum as a main component, as with upper wire member 30 in the first embodiment. Each of the plurality of upper wires 30a and 30b is a conductive wire or a conductive ribbon, for example. In the plan view of main surface 11a of semiconductor device body 11, each of the plurality of upper wires 30a and 30b has an elongated shape in the longitudinal direction of upper wire member 30. Since the plurality of upper wires 30a and 30b are disposed in parallel, in semiconductor apparatus 1c in the present embodiment, a current larger than that in semiconductor apparatus 1 in the first embodiment can be passed through semiconductor device 10.

Width W₁ of lower wire member 20 in the present embodiment is larger than width W₁ of lower wire member 20 in the first embodiment, such that the plurality of upper wires 30a and 30b can be stacked on lower wire member 20. Each of the plurality of upper wires 30a and 30b has a width W₄ smaller than width W₁ of lower wire member 20. In the plan view of main surface 11a of semiconductor device body 11, the plurality of upper wires 30a and 30b are disposed on lower wire member 20. In the plan view of main surface 11a of semiconductor device body 11, lower wire member 20 is disposed across the plurality of upper wires 30a and 30b. Accordingly, even when the number of the plurality of upper wires 30a and 30b increases, in the plan view of main surface 11a of semiconductor device body 11, portion 28 of upper wire member 30 located between end surface 21 and end surface 22 of lower wire member 20 does not protrude from lower wire member 20 in the transverse direction of upper wire member 30.

A method for manufacturing semiconductor apparatus 1c in the present embodiment will be described. The method for manufacturing semiconductor apparatus 1c in the present embodiment includes steps similar to those of the method for manufacturing semiconductor apparatus 1 in the first embodiment, and is different therefrom mainly in the following respect. In the method for manufacturing semiconductor apparatus 1c in the present embodiment, the plurality of upper wires 30a and 30b are permanently joined to metal layer 12 of semiconductor device 10 with lower wire member 20 being interposed therebetween in the permanent joining step (S23) shown in FIG. 5.

Semiconductor apparatus 1c and the method for manufacturing for the same in the present embodiment exhibit the following effect, in addition to the effect of semiconductor apparatus 1 and the method for manufacturing the same in the first embodiment.

In semiconductor apparatus 1c in the present embodiment, upper wire member 30 includes the plurality of upper wires 30a and 30b arranged in the transverse direction of upper wire member 30 (the y direction). The transverse direction of upper wire member 30 is perpendicular to the longitudinal direction of upper wire member 30 (the x direction), in the plan view of main surface 11a of semiconductor device body 11. In the plan view of main surface 11a of semiconductor device body 11, the plurality of upper wires 30a and 30b are disposed on lower wire member 20.

Accordingly, even when the number of the plurality of upper wires 30a and 30b is increased in order to pass a larger current through semiconductor device 10, lower wire member 20 can be reliably interposed between the plurality of upper wires 30a and 30b and metal layer 12. Semiconductor device 10 is prevented from being damaged when the plurality of upper wires 30a and 30b are joined. Reliability of semiconductor apparatus 1c is improved.

Further, width W₁ of lower wire member 20 increases such that the plurality of upper wires 30a and 30b can be stacked. The joining area between lower wire member 20 and metal layer 12 increases. Even when a thermal stress is repeatedly applied to a junction between lower wire member 20 and metal layer 12 while semiconductor apparatus 1c is used, a time taken until lower wire member 20 is divided by a crack increases. Accordingly, reliability of semiconductor apparatus 1c is improved.

When compared with a semiconductor apparatus in a comparative example (not shown) which includes the plurality of upper wires 30a and 30b and the plurality of lower wires 20a, 20b, and 20c, and in which each of the plurality of upper wires 30a and 30b is joined by a corresponding lower wire (see FIG. 11), the number of junctions between the lower wire member and the metal layer decreases in semiconductor apparatus 1c in the present embodiment. As the number of junctions decreases, the risk that the junction may be damaged by the thermal stress while semiconductor apparatus 1c is used decreases, and productivity of semiconductor apparatus 1c is improved. Accordingly, reliability and productivity of semiconductor apparatus 1c are improved.

### Fourth Embodiment

The present embodiment is directed to a power conversion apparatus to which semiconductor apparatuses 1, 1b, and 1c in the first to third embodiments described above are applied. Although the present disclosure is not limited to a specific power conversion apparatus, a case where semiconductor apparatus 1, 1b, or 1c of the present disclosure is applied to a three-phase inverter will be described below as a fourth embodiment.

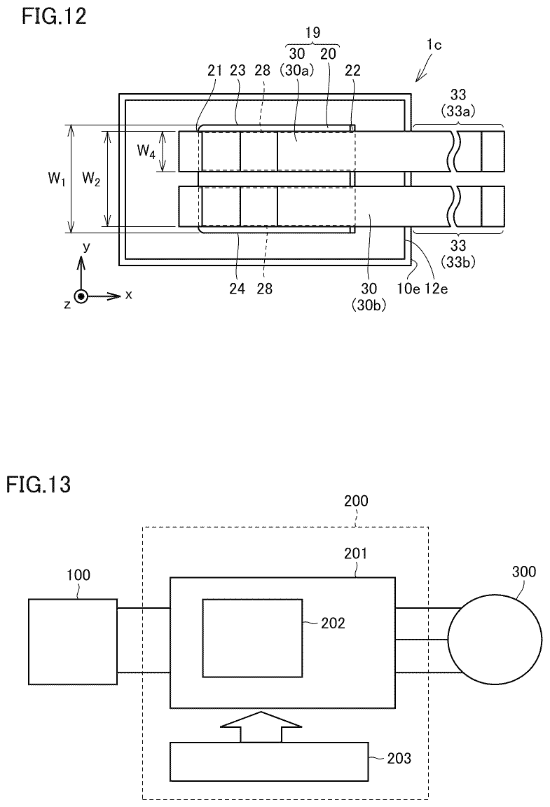

A power conversion system shown in FIG. 13 is composed of a power supply 100, a power conversion apparatus 200, and a load 300. Power supply 100 is a direct current (DC) power supply, and supplies DC power to power conversion apparatus 200. Power supply 100 is not particularly limited, and may be constituted by a DC system, a solar battery, or a storage battery, or may be constituted by a rectification circuit or an alternating current (AC)/DC converter connected to an AC system, for example. Power supply 100 may be constituted by a DC/DC converter to convert DC power outputted from a DC system into another DC power.

Power conversion apparatus 200 is a three-phase inverter connected between power supply 100 and load 300, and converts the DC power supplied from power supply 100 into AC power and supplies the AC power to load 300. As shown in FIG. 13, power conversion apparatus 200 includes a main conversion circuit 201 to convert the DC power into AC power and output the AC power, and a control circuit 203 to output a control signal for controlling main conversion circuit 201, to main conversion circuit 201.

Load 300 is a three-phase motor driven by the AC power supplied from power conversion apparatus 200. It should be noted that load 300 is not limited to a specific application, and is a motor mounted on a variety of electric appliances. For example, it is used as a motor for a hybrid vehicle, an electric vehicle, a railroad vehicle, an elevator, or an air conditioner.

Details of power conversion apparatus 200 will be described below. Main conversion circuit 201 includes a switching element (not shown) and a freewheeling diode (not shown). As the switching element switches a voltage supplied from power supply 100, main conversion circuit 201 converts the DC power supplied from power supply 100 into AC power, and supplies it to load 300. While main conversion circuit 201 may have various specific circuit configurations, main conversion circuit 201 in the present embodiment is a two-level three-phase full bridge circuit, and can be composed of six switching elements and six freewheeling diodes respectively in anti-parallel with the switching elements. At least one of the switching elements of main conversion circuit 201 is a switching element included in a semiconductor apparatus 202 corresponding to any one of semiconductor apparatuses 1, 1b, and 1c in the first to third embodiments described above. Every two switching elements of the six switching elements are connected in series to constitute upper and lower arms, and the upper and lower arms constitute phases (a U phase, a V phase, and a W phase) of the full bridge circuit. Then, output terminals of the upper and lower arms, that is, three output terminals of main conversion circuit 201, are connected to load 300.

Further, main conversion circuit 201 includes a drive circuit (not shown) to drive each switching element. The drive circuit may be embedded in semiconductor apparatus 202, or may be provided outside semiconductor apparatus 202. The drive circuit generates a drive signal to drive each switching element of main conversion circuit 201, and supplies the drive signal to a control electrode of each switching element of main conversion circuit 201. Specifically, it outputs a drive signal to set a switching element to an ON state and a drive signal to set a switching element to an OFF state, to the control electrode of each switching element, according to the control signal from control circuit 203. When the switching element is maintained in the ON state, the drive signal is a voltage signal more than or equal to a threshold voltage of the switching element (an ON signal), and when the switching element is maintained in the OFF state, the drive signal is a voltage signal less than or equal to the threshold voltage of the switching element (an OFF signal).

Control circuit 203 controls the switching elements of main conversion circuit 201 such that power is supplied to load 300. Specifically, it calculates a time when each switching element of main conversion circuit 201 should be in the ON state (an ON time), based on the power to be supplied to load 300. For example, it can control main conversion circuit 201 by PWM control that modulates the ON time of the switching element according to a voltage to be outputted to load 300. Then, it outputs a control command (control signal) to the drive circuit included in main conversion circuit 201, so as to output the ON signal to a switching element which is to be set to the ON state, and to output the OFF signal to a switching element which is to be set to the OFF state, at each time point. According to this control signal, the drive circuit outputs the ON signal or the OFF signal as a drive signal, to the control electrode of each switching element.

In the power conversion apparatus in the present embodiment, any one of semiconductor apparatuses 1, 1b, and 1c in the first to third embodiments is applied as semiconductor apparatus 202 constituting main conversion circuit 201. Accordingly, reliability and productivity of the power conversion apparatus can be improved.

Although the present embodiment has described an example where the present disclosure is applied to a two-level three-phase inverter, the present disclosure is not limited thereto, and is applicable to various power conversion apparatuses. Although the present embodiment has described a two-level power conversion apparatus, a three-level power conversion apparatus or a multi-level power conversion apparatus may be adopted, and when the power conversion apparatus supplies power to a single-phase load, the present disclosure may be applied to a single-phase inverter. When the power conversion apparatus supplies power to a DC load or the like, the present disclosure is applicable to a DC/DC converter or an AC/DC converter.

The power conversion apparatus to which the present disclosure is applied is not limited to the above case where the load is a motor. For example, the power conversion apparatus can also be used as a power supply apparatus for an electric discharge machine, a laser beam machine, an induction heating cooking device, or a non-contact power feeding system, and furthermore can also be used as a power conditioner for a solar power generation system, a power storage system, or the like.

It should be understood that the first to fourth embodiments disclosed herein are illustrative and non-restrictive in every respect. The scope of the present disclosure is defined by the scope of the claims, rather than the description above, and is intended to include any modifications within the scope and meaning equivalent to the scope of the claims.

### REFERENCE SIGNS LIST

1, 1b, 1c: semiconductor apparatus; 10: semiconductor device; 10e: periphery; 11: semiconductor device body; 11a: main surface; 12: metal layer; 12e: periphery; 19: wire member; 20: lower wire member; 20a, 20b, 20c: lower wire; 20p: conductive wire member, 21, 21a, 21b, 21c, 22, 22a, 22b, 22c: end surface; 23, 24: edge; 26: first portion; 27: second portion; 28: portion; 30: upper wire member; 30a, 30b: upper wire; 33: portion; 40: ultrasonic horn; 42: cutter; 100: power supply; 200: power conversion apparatus; 201: main conversion circuit; 202: semiconductor apparatus; 203: control circuit; 300: load.

1. A semiconductor apparatus comprising:
a semiconductor device including a semiconductor device body having a main surface, and a metal layer provided on the main surface;
a lower wire member; and
an upper wire member, wherein
the lower wire member includes a first end surface and a second end surface opposite to the first end surface, the first end surface and the second end surface are both end surfaces of the lower wire member in a longitudinal direction of the upper wire member, and in a plan view of the main surface, the first end surface and the second end surface are located inside a periphery of the semiconductor device,
the upper wire member is stacked on the lower wire member, and in the plan view of the main surface, a portion of the upper wire member is located outside the periphery of the semiconductor device,
the upper wire member is joined to the metal layer with the lower wire member being interposed therebetween, and
at least one of the first end surface and the second end surface is not in contact with both the metal layer and the upper wire member and is separated from both the metal layer and the upper wire member.

2. The semiconductor apparatus according to claim 1, wherein at least one of the first end surface or the second end surface is a cut end surface.

3. The semiconductor apparatus according to claim 1, wherein
the metal layer and the lower wire member are ultrasonically joined to each other, and
the lower wire member and the upper wire member are ultrasonically joined to each other.

4-5. (canceled)

6. The semiconductor apparatus according to claim 1, wherein, in the plan view of the main surface, the lower wire member has an elongated shape, and the longitudinal direction of the upper wire member extends along longitudinal direction of the lower wire member.

7. The semiconductor apparatus according to claim 1, wherein
in the plan view of the main surface, an entire width in a transverse direction of the upper wire member, of a portion of the upper wire member located between the first end surface and the second end surface of the lower wire member, overlaps the lower wire member, and
the transverse direction of the upper wire member is perpendicular to the longitudinal direction of the upper wire member, in the plan view of the main surface.

8-15. (canceled)

16. The semiconductor apparatus according to claim 1, wherein
the lower wire member includes a plurality of lower wires arranged in a transverse direction of the upper wire member, the transverse direction of the upper wire member being perpendicular to the longitudinal direction of the upper wire member, in the plan view of the main surface, and
in the plan view of the main surface, the upper wire member is disposed across the plurality of lower wires.

17. The semiconductor apparatus according to claim 1, wherein
the upper wire member includes a plurality of upper wires arranged in a transverse direction of the upper wire member, the transverse direction of the upper wire member being perpendicular to the longitudinal direction of the upper wire member, in the plan view of the main surface, and
in the plan view of the main surface, the plurality of upper wires are disposed on the lower wire member.

18. The semiconductor apparatus according to claim 1, wherein the lower wire member and the upper wire member are formed of a conductive material containing copper or aluminum as a main component.

19. The semiconductor apparatus according to claim 1, wherein the lower wire member and the upper wire member are each a conductive wire or a conductive ribbon.

20. The semiconductor apparatus according to claim 1, further comprising an insulating sealing member to seal the semiconductor device, the lower wire member, and the upper wire member.

21. A method for manufacturing a semiconductor apparatus, the method comprising:
temporarily joining a lower wire member to a metal layer of a semiconductor device,
the semiconductor device including a semiconductor device body having a main surface, and the metal layer provided on the main surface, the lower wire member including a first end surface and a second end surface opposite to the first end surface, in a plan view of the main surface, the first end surface and the second end surface being located inside a periphery of the semiconductor device;
stacking an upper wire member on the lower wire member, in the plan view of the main surface, a portion of the upper wire member being located outside the periphery of the semiconductor device, the first end surface and the second end surface being both end surfaces of the lower wire member in a longitudinal direction of the upper wire member; and
permanently joining the upper wire member to the metal layer of the semiconductor device with the lower wire member being interposed therebetween,
wherein at least one of the first end surface and the second end surface is not in contact with both the metal layer and the upper wire member and is separated from both the metal layer and the upper wire member.

22. The method for manufacturing the semiconductor apparatus according to claim 21, wherein
temporarily joining the lower wire member to the metal layer of the semiconductor device is ultrasonically joining the lower wire member to the metal layer of the semiconductor device while applying a first load and first ultrasonic vibration energy to the lower wire member,
permanently joining the upper wire member to the metal layer of the semiconductor device with the lower wire member being interposed therebetween is ultrasonically joining the upper wire member to the metal layer of the semiconductor device with the lower wire member being interposed therebetween while applying a second load and second ultrasonic vibration energy to the upper wire member, and
the first load is smaller than the second load, or the first ultrasonic vibration energy is smaller than the second ultrasonic vibration energy.

23. A power conversion apparatus comprising:
a main conversion circuit having the semiconductor apparatus according to claim 1, to convert inputted power and output the converted inputted power; and
a control circuit to output a control signal for controlling the main conversion circuit, to the main conversion circuit.
